(19) United States
(12) Patent Application Publication
(10) Pub. No.: US 2004/0008022 A1
(43) Pub. Date: Jan. 15, 2004

(54) Current sensor

(76) Inventors: Jeffrey L. Viola, Berkley, MI (US); William T. Moore, Ypsilanti, MI (US)

Correspondence Address: MACMILLAN, SOBANSKI & TODD, LLC, ONE MARITIME PLAZA-FOURTH FLOOR, 720 WATER STREET, TOLEDO, OH, 43604, US

(21) Appl. No.: 10/193,750

(22) Filed: Jul. 11, 2002

(51) Int. Cl. G01R 33/00

(52) U.S. Cl. 324/117 R

(57) ABSTRACT

An apparatus for sensing current passing through a conductor comprises a plurality of bi-directional magnetic pickups with low field sensing capability used in a common mode rejection configuration around the conductor without directly contacting the conductor. According to one embodiment of the invention, a plurality of bi-directional magnetic pickups is used around the trace of a circuit board without directly contacting the trace.

### BACKGROUND OF INVENTION

1. Field of the Invention

This invention generally relates to measuring and testing and more particularly relates to an apparatus for sensing current. Most particularly, the invention relates to an apparatus for sensing current passing through a conductor or a conducting trace of a circuit board without directly contacting the conductor or the trace.

2. Description of the Prior Art

Current sensors are generally known in the art. However, such sensors may have problems sensing current passing through a conductor or a conducting trace of the circuit board without directly contacting the conductor or the trace due to physical constraints about the conductor or the physical presence of the circuit board. A need thus exists for an apparatus for sensing current that overcomes this disadvantage.

### SUMMARY OF INVENTION

The present invention is directed towards an apparatus that meets the foregoing needs. The apparatus senses current passing through a conductor. The apparatus comprises a plurality of bi-directional magnetic pickups with low field sensing capability used in a common mode rejection configuration around the conductor without directly contacting the conductor. According to one embodiment of the invention, a plurality of bi-directional magnetic pickups is used around the trace of a circuit board without directly contacting the trace.

Various objects and advantages of this invention will become apparent to those skilled in the art from the following detailed description of the preferred embodiment, when read in light of the accompanying drawings.

### BRIEF DESCRIPTION OF DRAWINGS

FIG. 1 is a sectional perspective view of an apparatus for sensing current passing through a conducting trace of a circuit board.

FIG. 2 is a side elevational view of the apparatus illustrated in FIG. 1.

FIG. 3 is a top plan view of the apparatus illustrated in FIGS. 1 and 2.

FIG. 4 is a sectional perspective view of another apparatus for sensing current passing through a conducting trace of a circuit board.

FIG. 5 is a side elevational view of the apparatus illustrated in FIG. 4.

FIG. 6 is a top plan view of the apparatus illustrated in FIGS. 4 and 5.

FIG. 7 is a sectional perspective view of another apparatus for sensing current passing through a conducting trace of a circuit board.

FIG. 8 is a side elevational view of the apparatus illustrated in FIG. 7.

FIG. 9 is a side elevational view of another apparatus for sensing current passing through a conducting trace of a circuit board.

### DETAILED DESCRIPTION

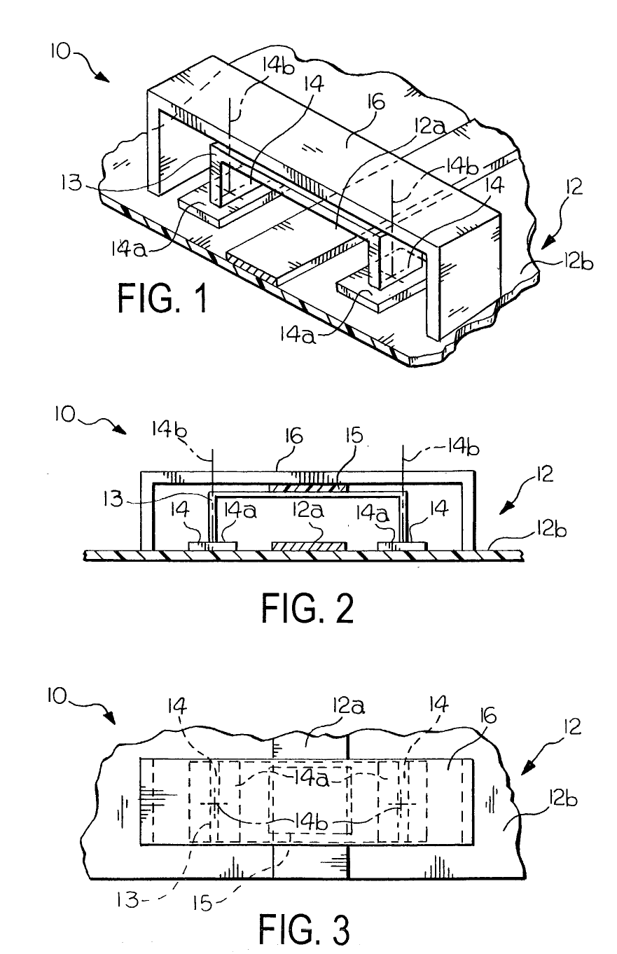

Referring now to the drawings, there is illustrated in FIGS. 1-3 an apparatus 10 according to the invention on a circuit board 12. The apparatus 10 senses current passing through a conductor or a conducting trace 12a of the circuit board 12 without directly contacting the conductor or the trace 12a. When current passes through the conductor or the trace 12a, a circumferential magnetic field surrounds the conductor or the trace 12a. A component of the magnetic field is sensed by the apparatus 10 to produce an output signal that correlates to the amount of current passing through the conductor or the trace 12a.

The apparatus 10 is comprised of a plurality of magnetic pickups with low field sensing capability. The magnetic pickups are bi-directional pickups that assign positive and negative values for the polarity of the magnetic fields being sensed. The pickups are used in a common mode rejection configuration around the current carrying conductor or trace 12a to cancel interfering magnetic fields from extraneous sources and directions.

The pickups illustrated in FIGS. 1-3 are in the form of a pair of diametrically disposed Hall plates 14 are held in a spaced relation to the conductor or affixed to the surface 12b of the circuit board 12 next to the trace 12a. The Hall plates 14 are placed on opposing side of the conductor or the trace 12a. Each Hall plate 14 has a planar surface 14a and a sensing axis 14b that is perpendicular to the planar surface 14a. A component of the magnetic field surrounding the conductor or the trace 12a is sensed by each Hall plate 14 through the sensing axis 14b.

The Hall plates 14 sense a component of the magnetic field surrounding the conductor or the trace 12a in only one direction through the sensing axis 14b. Magnetic fields in a direction other than that along the sensing axis 14b will not be sensed by the Hall plates 14.

A flux concentrator may be used to increase flux density at the Hall plates 14. The flux concentrator may be a single element, such as the U-shaped flux concentrator 13 illustrated in FIGS. 1-3, or a separate element (not shown) for each Hall plate 14. An insulator 15 may be used to hold the U-shaped flux concentrator 13 in position.

Each Hall plate 14 produces an output signal that correlates to the magnetic field sensed through the sensing axis 14b. The Hall plates 14 are arranged so that the output of the two Hall plates 14, when subtracted or summed (depending on the orientation or sensing polarities of the Hall plates 14), rejects any extraneous magnetic field picked up by the Hall plates 14 as a common mode signal. Consequently, only uniformed magnetic fields produced by the current flowing through the conductor or trace 12a will be sensed by the Hall plates 14.

To prevent extraneous gradient fields (e.g., from other components) from being sensed by the Hall plates 14, one or more shields 16 are placed over or about the Hall plates 14. The shield or shields 16 should be placed a sufficient distance away from the Hall plates 14 so that the shield or shields 16 do not function as a flux concentrator. This would unfavorably distort the magnetic field sensed by the Hall plates 14. Placement of the shield or shields 16 should take into consideration the maximum current to be carried by the trace 12a and thus the maximum magnetic field produced by the current. Incorrect placement of the shield or shields 16 may interfere with the ability of the Hall plates 14 to function linearly or diminish the effectiveness of attenuating extraneous gradient fields.

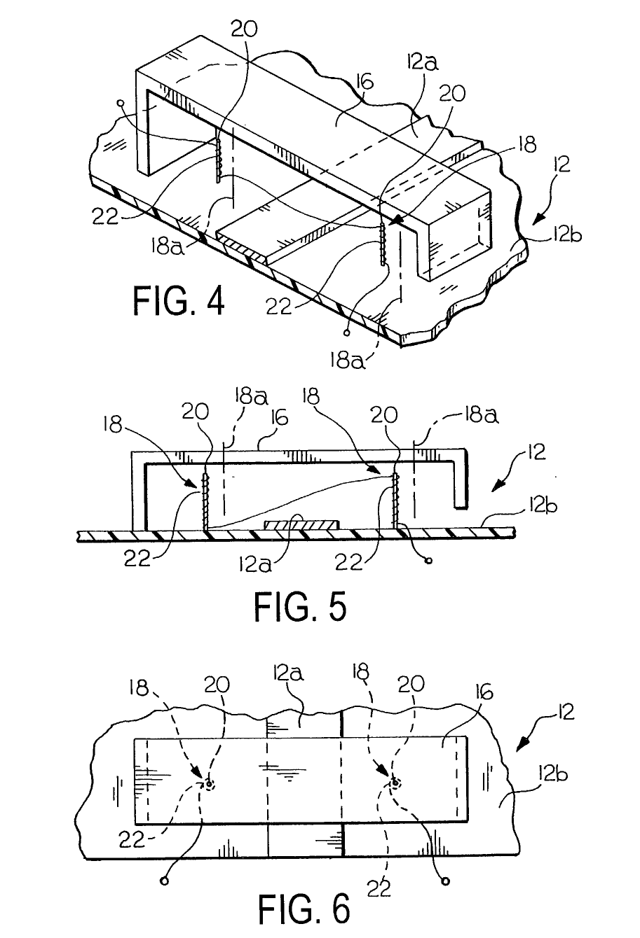

Another embodiment of the invention is illustrated in FIGS. 4-6. The magnetic pickups in this embodiment are in the form of a pair of diametrically disposed flux gate sensors 18 placed next to the conductor or the trace 12a. Like the Hall plates 14 described above, the flux gates 18 are placed on opposing sides of the conductor or the trace 12a. Each flux gate 18 has a magnetic core 20 and a coil 22 wound about the magnetic core 20. The magnetic core 20 is oriented perpendicular to the planar surface 12b of the circuit board 12. Each flux gate 18 has a sensing axis 18a that is parallel to the magnetic core 20, or perpendicular to the surface 12b of the circuit board 12. A component of the magnetic field surrounding the conductor or the trace 12a is sensed by each flux gate 18 through the sensing axis 18a.

Similar to the Hall plates 14 described above, the flux gates 18 sense a component of the magnetic field surrounding the conductor or the trace 12a in only one direction through the sensing axis 18a. Magnetic fields in a direction other than that along the sensing axis 18a will not be sensed by the flux gates 18.

Each flux gate 18 produces an output signal that correlates to the magnetic field sensed through the sensing axis 18a. The flux gates 18 are arranged so that the output of the two flux gates 18, when subtracted or summed (depending on the orientation or sensing polarities of the flux gates 18), rejects any extraneous magnetic field picked up by the flux gates 18 as a common mode signal. Consequently, only uniformed magnetic fields produced by the current flowing through the conductor or the trace 12a will be sensed by the flux gates 18.

To prevent extraneous gradient fields from being sensed by the flux gates 18, one or more shields 16 are placed over or about the flux gates 18. The shield or shields 16 should be placed a sufficient distance away from the flux gates 18 so that the shield or shields 16 do not function as a flux concentrator. This would unfavorably distort the magnetic field sensed by the flux gates 18. Placement of the shield or shields 16 should take into consideration the maximum current to be carried by the conductor or the trace 12a and thus the maximum magnetic field produced by the current. Incorrect placement of the shield or shields 16 may interfere with the ability of the flux gates 18 to function linearly or diminish the effectiveness of attenuating extraneous gradient fields.

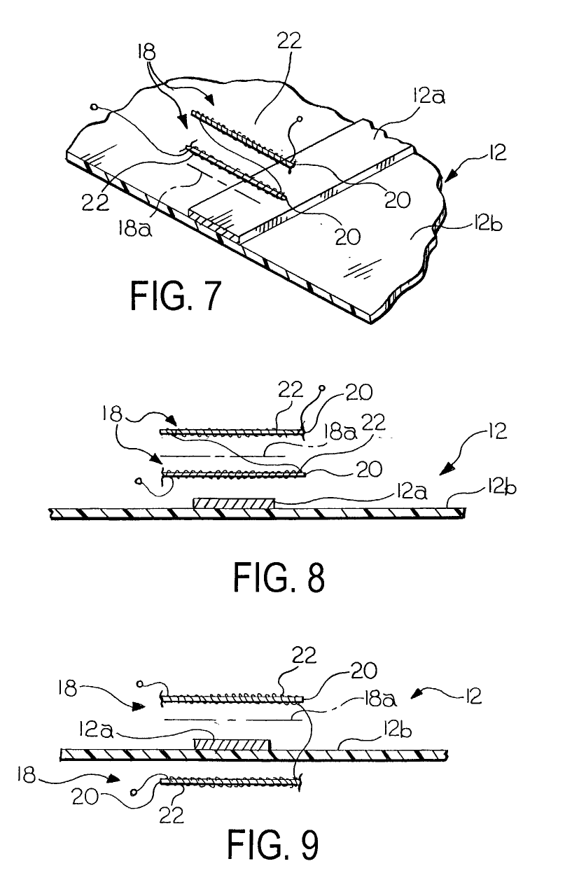

Yet another embodiment of the invention is illustrated in FIGS. 7 and 8. Like the immediately preceding embodiment of the invention, the magnetic pickups in this embodiment are in the form of a pair of flux gates 18 placed next to the conductor or the trace 12a. However, the flux gates 18 according to this embodiment are placed side-by-side over the conductor or the trace 12a in a plane that is perpendicular relative to the longitudinal axis of the conductor or the trace 12b. That is to say, both flux gates 18 exist in the same plane and perpendicular to the conductor or trace 12a. Each flux gate 18 has a magnetic core 20 and a coil 22 wound about the magnetic core 20. The magnetic core 20 is oriented parallel to the planar surface 12b of the circuit board 12. Each flux gate sensor 18 has a sensing axis 18a that is parallel to the magnetic core 20 and thus parallel to the planar surface 12b of the circuit board 12. A component of the magnetic field surrounding the conductor or the trace 12a is sensed by each flux gate 18 through the sensing axis 18a.

Similar to the flux gates 18 described above, these flux gates 18 sense a component of the magnetic field surrounding the conductor or the trace 12a in only one direction through the sensing axis 18a. Magnetic fields in a direction other than that along the sensing axis 18a will not be sensed by the flux gates 18.

Each flux gate 18 produces an output signal that correlates to the magnetic field sensed through the sensing axis 18a in a weighted sum or subtraction correlating to the difference in distance with respect to trace 12a. The flux gates 18 are arranged so that the output of the two flux gates 18, when summed or subtracted (depending on the orientation or sensing polarities of the flux gates 18), rejects any extraneous magnetic field picked up by the flux gates 18 as a common mode signal. Consequently, only uniformed magnetic fields produced by the current flowing through the conductor or the trace 12a will be sensed by the flux gates 18.

To prevent extraneous gradient fields from being sensed by the flux gates 18, one or more shields (not shown) are placed over or about the flux gates 18. The shield or shields should be placed a sufficient distance away from the flux gates 18 so that the shield or shields do not function as a flux concentrator. This would unfavorably distort the magnetic field sensed by the flux gates 18. Placement of the shield or shields should take into consideration the maximum current to be carried by the conductor or the trace 12a and thus the maximum magnetic field produced by the current. Incorrect placement of the shield or shields may interfere with the ability of the flux gates 18 to function linearly or diminish the effectiveness of attenuating extraneous gradient fields.

Another embodiment of the invention is illustrated in FIG. 9. This embodiment is similar to that shown in FIGS. 7 and 8 and described immediately above. Like the immediately preceding embodiment of the invention, the magnetic pickups in this embodiment are in the form of a pair of flux gates 18 placed next to the conductor or the trace 12a. However, the flux gates 18 according to this embodiment are equidistantly spaced above and below the conductor or the trace 12a.

Current sensors according to the present invention sense directly from the conductor or the conducting trace of the circuit board without interrupting or splicing into the conductor or the trace. Moreover, the current sensors do not completely encircle the conductor or the trace and thus are easy to install. By using the magnetic pickups in a common mode rejection configuration, and further by placing one or more shields over the magnetic pickups, interference from magnetic fields from extraneous sources and directions is eliminated.

The present invention is not intended to be limited in scope to the magnetic pickups shown and described but may be carried out by other suitable pickups that interrupt or splice into the conductor or the trace of a circuit board.

The principle and mode of operation of this invention have been explained and illustrated in its preferred embodiment. However, it must be understood that this invention can be practiced otherwise than as specifically explained and illustrated without departing from its spirit or scope.

What is claimed is:

1. An apparatus for sensing current passing through a conductor, comprising:
a plurality of bi-directional magnetic pickups with low field sensing capability used in a common mode rejection configuration around the conductor without directly contacting the trace.

2. In combination:
a circuit board having a trace; and
a plurality of bi-directional magnetic pickups with low field sensing capability used in a common mode rejection configuration around the conductor without directly contacting the trace.

3. The combination of claim 2, wherein the pickups are in the form of a pair of diametrically disposed Hall plates affixed to the circuit board next to the trace, each of the Hall plates having a planar surface and a sensing axis that is perpendicular to the planar surface.

4. The combination of claim 3, wherein the Hall plates are placed on opposing sides of the trace.

5. The combination of claim 3, further comprising one or more shields placed over the Hall plates to prevent extraneous gradient fields from being sensed by the Hall plates.

6. The combination of claim 5, wherein the one or more shields are placed a sufficient distance away from the Hall plates so that the one or more shields do not function as a flux concentrator.

7. The combination of claim 2, further including one or more flux concentrators arranged to increase flux density at the Hall plates.

8. The combination of claim 7, wherein the one or more flux concentrators are a single U-shaped element.

9. The combination of claim 2, wherein the pickups are in the form of a pair of diametrically disposed flux gates placed next to the trace.

10. The combination of claim 9, wherein the flux gates are placed on opposing sides of the trace, each of the flux gates having a magnetic core and a coil wound about the magnetic core, the magnetic core being oriented perpendicular to a surface of the circuit board, each flux gate having a sensing axis that is parallel to the magnetic core and perpendicular to the surface of the circuit board.

11. The combination of claim 10, wherein the flux gates are oriented to sense a component of the magnetic field surrounding the trace in only one direction through the sensing axis.

12. The combination of claim 10, wherein the flux gates are arranged so that the output of the flux gates, when subtracted or summed, rejects any extraneous magnetic field picked up by the flux gates as a common mode signal.

13. The combination of claim 10, further including one or more shields placed over the flux gates, the shields being placed a sufficient distance away from the flux gates so that the shield does not function as a flux concentrator.

14. The combination of claim 2, wherein the pickups are in the form of flux gates placed over the trace, the flux gates being placed in side-by-side relation to one another and in a common plane that is perpendicular relative to a longitudinal axis of the trace, each of the flux gates having a magnetic core and a coil wound about the magnetic core, the magnetic core being oriented substantially parallel to the surface of the circuit board and having a sensing axis that is parallel to the magnetic core and thus parallel to a surface of the circuit board.

15. The combination of claim 14, wherein the flux gates are arranged so as to produce an output signal that, when summed or subtracted, rejects any extraneous magnetic field picked up by the flux gates as a common mode signal.

16. The combination of claim 14, further including one or more shields placed over the flux gates, the shields being placed a sufficient distance away from the flux gates so that the one or more shields do not function as a flux concentrator.

17. The combination of claim 9, wherein the flux gates are arranged so that each of the flux gates produces an output signal that correlates to a magnetic field being sensed through a sensing axis of the flux gates in a weighted sum or subtraction correlating to a difference in distance between each of the flux gates and the trace.

18. The combination of claim 14, further including one or more shields placed over the flux gates, the shields being placed a sufficient distance away from the flux gates so that the one or more shields do not function as a flux concentrator.
